(19) United States
(12) Patent Application Publication
(10) Pub. No.: US 2025/0105211 A1
(43) Pub. Date: Mar. 27, 2025

(54) SEMICONDUCTOR DEVICE INCLUDING SIDE INTERCONNECTION

(71) Applicant: SK hynix Inc., Gyeonggi-do (KR)

(72) Inventor: Nam Jae LEE, Gyeonggi-do (KR)

(21) Appl. No.: 18/419,558

(22) Filed: Jan. 23, 2024

(30) Foreign Application Priority Data
Sep. 26, 2023 (KR) 10-2023-0129120

(51) Int. Cl. H01L 25/065; H01L 23/00

(52) U.S. Cl. CPC H01L 25/0657; H01L 24/32; H01L 2224/32058; H01L 2224/32059; H01L 2224/32145; H01L 2225/06551; H01L 2924/182

(57) ABSTRACT

A semiconductor device may include a stack structure having a plurality of semiconductor chips. Each of the plurality of semiconductor chips may have an interlayer insulating disposed over or on a substrate, a chip top interconnection disposed over or on the interlayer insulating layer and a chip top insulating layer disposed over or on the chip top interconnection. A side interconnection disposed over or on a side surface of the stack structure and connected to the chip top interconnection may be provided. A plurality of insulating patterns May be disposed between the stack structure and the side interconnection. Each of the plurality of insulating patterns may contact a side surface of the substrate and the interlayer insulating layer of adjacent one among the plurality of semiconductor chips.

### CROSS-REFERENCE TO RELATED APPLICATION

The present application claims priority under 35 U.S.C. § 119 (a) to Korean Patent Application No. 10-2023-0129120 filed in the Korean Intellectual Property Office on Sep. 26, 2023, which is incorporated herein by reference in its entirety.

### BACKGROUND

### 1. Technical Field

Various embodiments of the present invention generally relate to a semiconductor device and more particularly to a semiconductor device including side interconnections and a method for forming the same.

### 2. Related Art

In response to the demand for high integration of semiconductor devices, technology for stacking a plurality of semiconductor chips is being attempted. Each of the plurality of semiconductor chips includes a plurality of input/output interconnections. Each of the plurality of input/output interconnections should be connected to a corresponding one among a plurality of external terminals. Connecting in parallel the plurality of input/output interconnections and the plurality of external terminals to implement a semiconductor device with high operation speed presents serious technical challenges and limitations.

### SUMMARY

Various embodiments of the disclosed technology are directed to providing a semiconductor device which has fast operation speed and is advantageous for high integration. Various embodiments of the disclosed technology are also directed to providing a method for making the semiconductor device.

In an embodiment, a semiconductor device may include a stack structure having a plurality of semiconductor chips. Each of the plurality of semiconductor chips may have an interlayer insulating layer disposed over or on a substrate, a chip top interconnection disposed over or on the interlayer insulating layer and a chip top insulating layer disposed over or on the chip top interconnection. A side interconnection disposed over or on a side surface of the stack structure and connected to the chip top interconnection may be provided. A plurality of insulating patterns may be disposed between the stack structure and the side interconnection. Each of the plurality of insulating patterns may contact a side surface of the substrate and the interlayer insulating layer of adjacent one among the plurality of semiconductor chips.

In an embodiment, a semiconductor device may include a stack structure having a plurality of semiconductor chips. Each of the plurality of semiconductor chips may have an interlayer insulating layer disposed over or on a substrate, a chip top interconnection disposed over or on the interlayer insulating layer and a chip top insulating layer disposed over or on the chip top interconnection. A side interconnection disposed over or on a side surface of the stack structure and connected to the chip top interconnection may be provided. A plurality of insulating patterns may be disposed between the stack structure and the side interconnection. Each of the plurality of insulating patterns may be aligned with a side surface of the substrate.

In an embodiment, a semiconductor device may include a stack structure having a plurality of semiconductor chips. Each of the plurality of semiconductor chips may have an interlayer insulating disposed over or on a substrate, a chip top interconnection disposed over or on the interlayer insulating layer and a chip top insulating layer disposed over or on the chip top interconnection. A side interconnection disposed over or on a side surface of the stack structure and connected to the chip top interconnection may be provided. An insulating pattern may be disposed between the stack structure and the side interconnection. The insulating pattern may contact side surfaces of the substrate, the interlayer insulating layer and the chip top insulating layer.

According to the embodiments of the disclosed technology, a plurality of side interconnections which are vertically disposed on the side surfaces of a stack structure may be provided. The stack structure may include a plurality of semiconductor chips which are sequentially stacked. A plurality of insulating patterns may be disposed between the plurality of semiconductor chips and the plurality of the side interconnections. The plurality of side interconnections may be connected to chip top interconnections, respectively, of the plurality of semiconductor chips. It is possible to implement a semiconductor device which has fast operation speed and is advantageous for high integration.

These and other features and advantages of the present invention will become apparent to those skilled in the art from the following drawings and detailed description of specific embodiments of the present invention.

### BRIEF DESCRIPTION OF THE DRAWINGS

FIG. 1 is a cross-sectional view schematic illustrating a semiconductor device based on embodiments of the disclosed technology.

FIGS. 2 to 6 are partial views illustrating a part of FIG. 1.

FIG. 7 is a layout diagram illustrating the semiconductor device based on the embodiments of the disclosed technology.

FIGS. 8, 9, 11, 22 and 29 to 32 are cross-sectional view schematics illustrating methods for forming the semiconductor device based on the embodiments of the disclosed technology.

FIG. 10 is a layout diagram illustrating the semiconductor device based on the embodiments of the disclosed technology.

FIGS. 12 to 21 are partial views illustrating a part of FIG. 11.

FIGS. 23 to 28 are partial views illustrating a part of FIG. 22.

### DETAILED DESCRIPTION

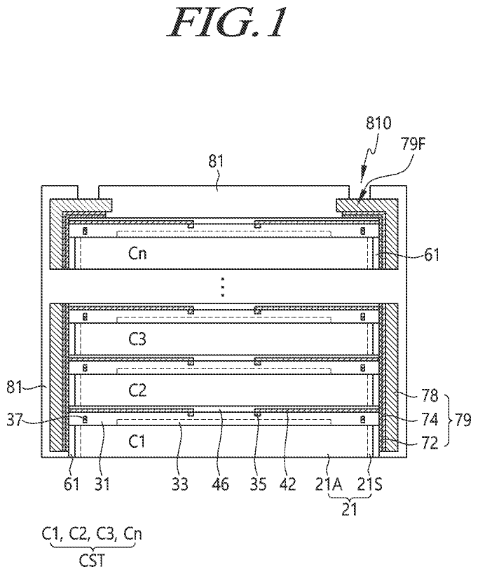

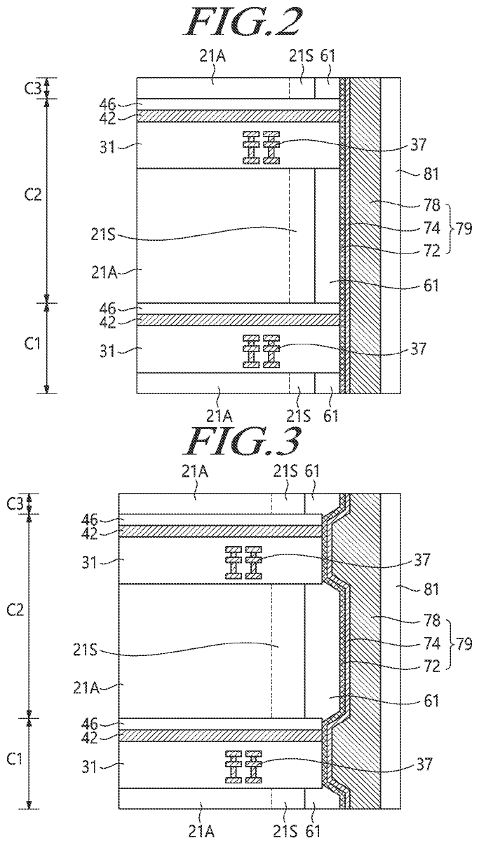

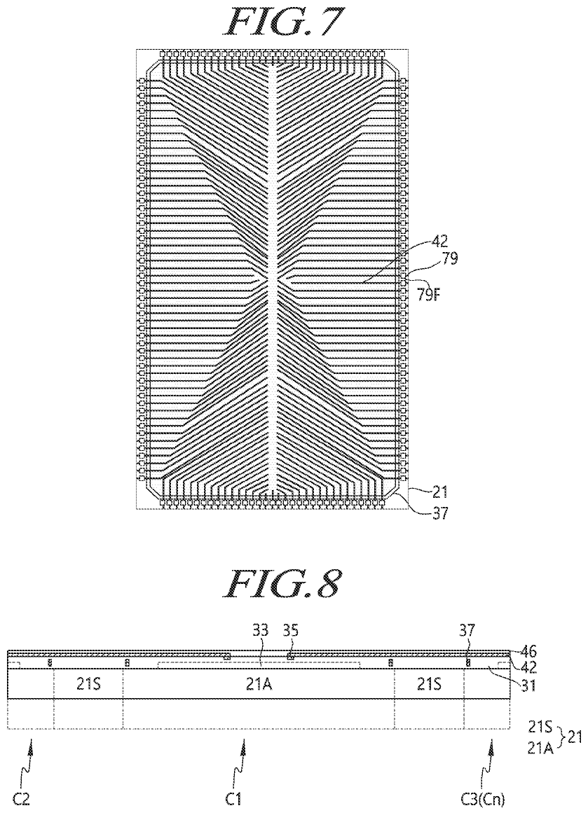

FIG. 1 is a cross-sectional view schematic illustrating a semiconductor device based on embodiments of the disclosed technology, FIGS. 2 to 6 are partial views illustrating a part of FIG. 1, and FIG. 7 is a layout diagram. The semiconductor device based on some embodiments of the disclosed technology may include a high bandwidth memory (HBM), a dynamic random access memory (DRAM), a static random access memory (SRAM), a flash memory, a magnetoresistive random access memory (MRAM), a phase-change random access memory (PRAM), a ferroelectric random access memory (FRAM), a resistive random access memory (RRAM), or a combination thereof.

Referring to FIG. 1, the semiconductor device based on the embodiments of the disclosed technology may include a stack structure CST, a plurality of the insulating patterns 61, a plurality of side interconnections 79, and a protective insulating layer 81.

The stack structure CST may include a plurality of semiconductor chips C1, C2, C3, . . . and Cn which are sequentially stacked. The plurality of semiconductor chips C1, C2, C3, . . . and Cn may include a first semiconductor chip C1, a second semiconductor chip C2, a third semiconductor chip C3 and an nth semiconductor chip Cn. Each of the plurality of semiconductor chips C1, C2, C3, . . . and Cn may include a substrate 21, an interlayer insulating layer 31 formed over or on the substrate 21, a plurality of integrated circuits 33, a plurality of internal interconnections 35, a guard ring 37, a plurality of chip top interconnections 42, and a chip top insulating layer 46. The substrate 21 may include an active region 21A and an outer region 21S. The outer region 21S may be disposed at an outermost side edge part of the substrate 21. The outer region 21S may be continuous outside the active region 21A. The outer region 21S may include a scribe lane, i.e., a narrow area for facilitating the separation of the semiconductor device during a dicing process. The outer region 21S may be disposed outside the guard ring 37.

Each of the plurality of the side interconnections 79 may be disposed on the side surface of the stack structure CST and extend over or onto the top surface of the stack structure CST covering a side portion of the top surface of the stack structure CST. Each of the plurality of the side interconnections 79 may be connected to a corresponding at least one among the plurality of chip top interconnections 42. Each of the plurality of the side interconnections 79 may be a multi-layer structure and may include a barrier layer 72, a seed layer 74 formed on the barrier layer 72, and a conductive line 78 formed on the seed layer 74. Each of the plurality of the side interconnections 79 may include an external connection terminal 79F on a portion thereof extending over or onto the top surface of the stack structure CST. In an embodiment, each of the barrier layer 72 and the seed layer 74 may optionally be omitted. Each of the barrier layer 72 and the seed layer 74 may be a single layer or a multi-layer.

The plurality of the insulating patterns 61 may be disposed between the stack structure CST and the plurality of the side interconnections 79. As shown in the embodiment of FIG. 1, each of the plurality of the insulating patterns 61 may be aligned on the side surface of the substrate 21 of each one of the plurality of semiconductor chips C1, C2, C3, . . . and Cn. Each of the plurality of the insulating patterns 61 may directly contact the side surface of the substrate 21 and the bottom surface of the interlayer insulating layer 31. Each of the plurality of the insulating patterns 61 except for the lowermost and uppermost ones may directly contact the top surface of an adjacent chip top insulating layer 46.

The protective insulating layer 81 may cover the stack structure CST, the uppermost ones of the plurality of the insulating patterns 61 and the plurality of the side interconnections 79. The protective insulating layer 81 may cover the lowermost ends of the plurality of the side interconnections 79. Openings 810 which expose the external connection terminals 79F may be provided through the protective insulating layer 81.

The second semiconductor chip C2 may be stacked over or on the first semiconductor chip C1, and the third semiconductor chip C3 may be stacked over or on the second semiconductor chip C2. For example, referring to FIG. 2, the second semiconductor chip C2 may be stacked on the first semiconductor chip C1, and the third semiconductor chip C3 may be stacked on the second semiconductor chip C2. Each of the chip top insulating layer 46 of the first semiconductor chip C1 and the chip top insulating layer 46 of the second semiconductor chip C2 may include a planarized top surface. The bottom surface of the substrate 21 of the second semiconductor chip C2 may directly contact the chip top insulating layer 46 of the first semiconductor chip C1. The bottom surface of the substrate 21 of the third semiconductor chip C3 may directly contact the chip top insulating layer 46 of the second semiconductor chip C2.

The substrate 21 of the second semiconductor chip C2 may include the active region 21A and the outer region 21S which is a continuous region formed on a side edge of the active region 21A. The outer region 21S may cover a side edge of the active region 21A. The interlayer insulating layer 31 of the second semiconductor chip C2 may cover the top surface of the active region 21A and the tope surface of the outer region 21S. The guard ring 37 may be disposed in the interlayer insulating layer 31 of the second semiconductor chip C2. The guard ring 37 may be disposed over the active region 21A and may be adjacent to the outer region 21S. The chip top interconnections 42 of the second semiconductor chip C2 may be disposed on the interlayer insulating layer 31 to extend onto the outer region 21S across the guard ring 37 from the active region 21A. The chip top insulating layer 46 of the second semiconductor chip C2 may be formed on the interlayer insulating layer 31 to completely cover the chip top interconnections 42. Each of the first semiconductor chip C1, the third semiconductor chip C3 and the nth semiconductor chip Cn may include the substrate 21, the interlayer insulating layer 31, the guard ring 37, the chip top interconnections 42 and the chip top insulating layer 46 which are similar to those of the second semiconductor chip C2.

A corresponding one among the plurality of the insulating patterns 61 may be aligned on the side surface of the substrate 21 of the second semiconductor chip C2. The corresponding one among the plurality of the insulating patterns 61 may be delimited between the interlayer insulating layer 31 of the second semiconductor chip C2 and the chip top insulating layer 46 of the first semiconductor chip C1. The corresponding one among the plurality of the insulating patterns 61 may directly contact the side surface of the substrate 21 of the second semiconductor chip C2, the bottom surface of the interlayer insulating layer 31 of the second semiconductor chip C2 and the top surface of the chip top insulating layer 46 of the first semiconductor chip C1. Similarly, each of the plurality of the insulating patterns 61 may be disposed on the side surface of the substrate 21 of a corresponding one among the plurality of semiconductor chips C1, C2, C3, . . . and Cn.

The side interconnections 79 may extend on the side surfaces of the plurality of semiconductor chips C1, C2, C3, . . . and Cn in a vertical direction. The corresponding one among the plurality of the insulating patterns 61 may be interposed between the barrier layer 72 of each side interconnection 79 and the substrate 21 of the second semiconductor chip C2. The barrier layer 72 of each side interconnection 79 may directly contact the side surface of the corresponding one among the plurality of the insulating patterns 61. The barrier layer 72 of each side interconnection 79 may cross, in the vertical direction, the side surfaces of the interlayer insulating layer 31, each chip top interconnection 42 and the chip top insulating layer 46 of the second semiconductor chip C2. The barrier layer 72 of each side interconnection 79 may directly contact the side surfaces of the interlayer insulating layer 31, each chip top interconnection 42 and the chip top insulating layer 46 of the second semiconductor chip C2.

Similarly, the barrier layer 72 of each side interconnection 79 may cross the side surfaces of the interlayer insulating layer 31, each chip top interconnection 42 and the chip top insulating layer 46 of each of the plurality of semiconductor chips C1, C2, C3, . . . and Cn in the vertical direction. The barrier layer 72 of each side interconnection 79 may directly contact the side surfaces of the interlayer insulating layer 31, each chip top interconnection 42 and the chip top insulating layer 46 of each of the plurality of semiconductor chips C1, C2, C3, . . . and Cn.

The seed layer 74 may be disposed on the barrier layer 72 and the conductive line 78 may be disposed on the seed layer 74. The seed layer 74 may be interposed between the barrier layer 72 and the conductive line 78. The protective insulating layer 81 may cover the conductive line 78.

Referring to FIG. 3, a corresponding one among the plurality of the insulating patterns 61 may be aligned on the side surface of the substrate 21 of the second semiconductor chip C2. The corresponding one among the plurality of the insulating patterns 61 may protrude outward out of the side surface of the interlayer insulating layer 31 of the second semiconductor chip C2. The corresponding one among the plurality of the insulating patterns 61 may partially extend onto the side surface of the interlayer insulating layer 31 of the second semiconductor chip C2. The corresponding one among the plurality of the insulating patterns 61 may directly contact the side surface of the interlayer insulating layer 31 of the second semiconductor chip C2. The uppermost end of the corresponding one among the plurality of the insulating patterns 61 may be limited to a level lower than the lowermost end of each chip top interconnection 42 of the second semiconductor chip C2.

The corresponding one among the plurality of the insulating patterns 61 may protrude outward out of the side surface of the chip top insulating layer 46 of the first semiconductor chip C1. The corresponding one among the plurality of the insulating patterns 61 may partially extend onto the side surface of the chip top insulating layer 46 of the first semiconductor chip C1. The corresponding one among the plurality of the insulating patterns 61 may directly contact the side surface of the chip top insulating layer 46 of the first semiconductor chip C1. The lowermost end of the corresponding one among the plurality of the insulating patterns 61 may be limited to a level higher than the uppermost end of each chip top interconnection 42 of the first semiconductor chip C1.

In the embodiment, of FIG. 3 the side interconnections 79 may have a plurality of alternating protrusions and valleys on at least one of their sides that is adjacent to the plurality of the semiconductor chips C1, C2, C3, . . . . Cn, with the protrusions being in direct contact with the sides of the interlayer insulating layers 31, the chip top interconnections 42, and the chip top insulating layers 46, while the valleys are in direct contact with the insulating patterns 61

Each of the plurality of the insulating patterns 61 may have a similar configuration to the corresponding one among the plurality of the insulating patterns 61 aligned on the side surface of the substrate 21 of the second semiconductor chip C2.

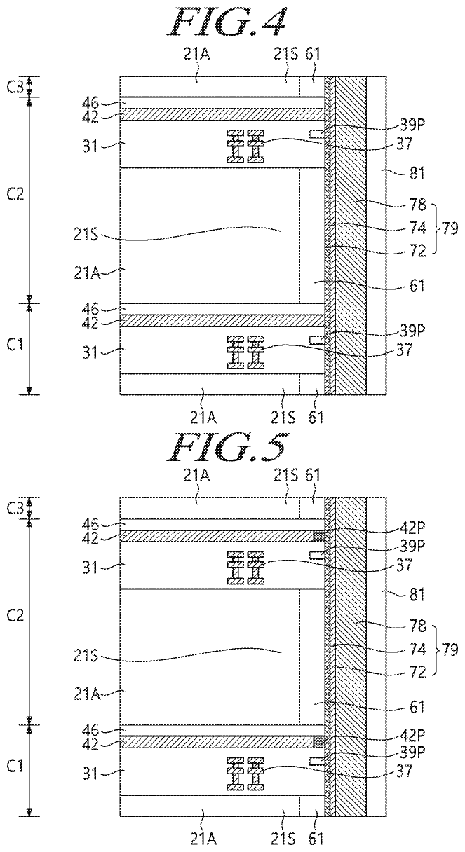

Referring to FIG. 4, a capping layer 39P may be disposed in the interlayer insulating layer 31 over the outer region 21S of the second semiconductor chip C2. The capping layer 39P may be disposed at a level lower than the bottom surface of each chip top interconnection 42 of the second semiconductor chip C2, i.e., the capping layer 39P may not contact the chip top interconnection 42. One side surface of the capping layer 39P may directly contact the barrier layer 72 of the side interconnection 79. Similarly, a capping layer 39P may be disposed in the interlayer insulating layer 31 of each of the plurality of semiconductor chips C1, C2, C3, . . . and Cn.

Referring to FIG. 5, a conductive plug 42P may be disposed between each side interconnection 79 and each chip top interconnection 42 of the second semiconductor chip C2. The conductive plug 42P may be disposed between the interlayer insulating layer 31 and the chip top insulating layer 46 over the outer region 21S, and may be in direct contact with the interlayer insulating layer 31, and the chip top insulating layer 46. The thickness of the conductive plugs 42P may be substantially the same as that of the chip top interconnections 42. The side surface of the conductive plugs 42P may directly contact the barrier layer 72 of each side interconnection 79. Hence, a conductive plug 42P may be disposed between each side interconnection 79 and each chip top interconnection 42 of each of the plurality of semiconductor chips C1, C2, C3, . . . and Cn.

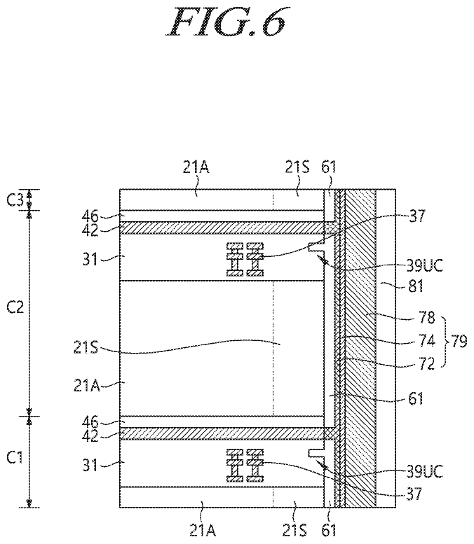

Referring to FIG. 6, the insulating pattern 61 may be of an integral type meaning that a single continuous insulating pattern may cover the side surfaces of the substrate 21, the interlayer insulating layer 31 and the chip top insulating layer 46 of each of the chips. The insulating pattern 61 may cover the side surfaces of the plurality of semiconductor chips C1, C2, C3, . . . and Cn. The insulating pattern 61 may directly contact the side surfaces of substrates 21, interlayer insulating layers 31 and chip top insulating layers 46. The insulating pattern 61 may fill first undercut regions 39UC which are formed by removing dummy patterns. Each side interconnection 79 may be connected to each chip top interconnection 42 by passing through the insulating pattern 61. In the embodiment of FIG. 6, the insulating pattern 61 may not cover the side of the corresponding chip top interconnection 42.

Referring to FIG. 7, each of the plurality of the side interconnections 79 may be connected to a corresponding at least one of the plurality of chip top interconnections 42. The plurality of chip top interconnections 42 may be disposed to cross the guard ring 37. Each of the plurality of the side interconnections 79 may include the external connection terminal 79F. External connection terminals 79F are illustrated to be adjacent to the edge of the substrate 21, but may be disposed at various positions to have various arrangements.

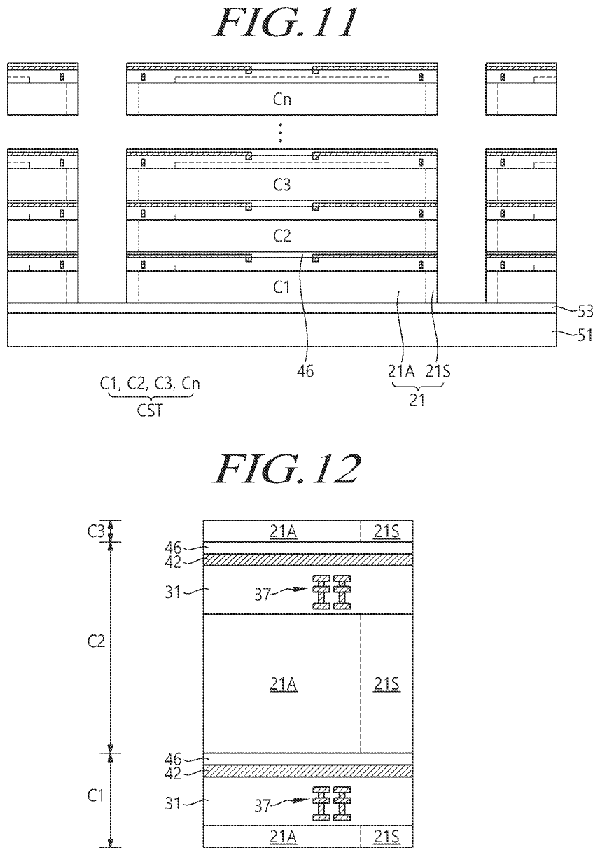

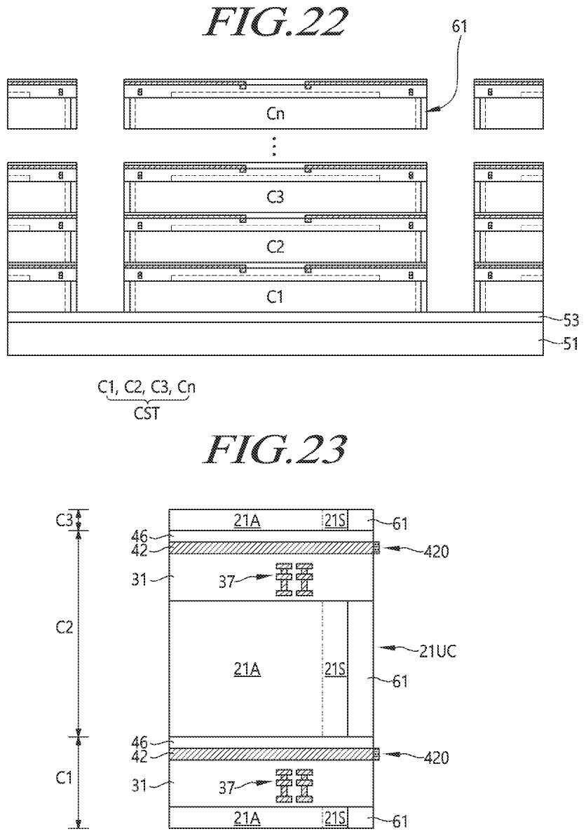

FIGS. 8, 9, 11, 22 and 29 to 32 are cross-sectional view schematics illustrating methods for forming the semiconductor device based on the embodiments of the disclosed technology, FIG. 10 is a layout diagram, FIGS. 12 to 21 are partial views illustrating a part of FIG. 11, and FIGS. 23 to 28 are partial views illustrating a part of FIG. 22.

Referring to FIG. 8, a plurality of semiconductor chips C1, C2, C3, . . . and Cn may be formed on a substrate 21. The substrate 21 may include a semiconductor substrate such as a silicon wafer or a silicon on insulator (SOI) wafer. The substrate 21 may include a plurality of active regions 21A and a plurality of outer regions 21S. The plurality of outer regions 21S may be disposed between the plurality of active regions 21A. In other words, the plurality of the active regions 21A and the plurality of the outer regions 21S may be alternating with each other.

An interlayer insulating layer 31 may be formed on the substrate 21. A plurality of integrated circuits 33, a plurality of internal interconnections 35 and a plurality of guard rings 37 may be formed in the interlayer insulating layer 31. A plurality of chip top interconnections 42 may be formed on the interlayer insulating layer 31. The plurality of integrated circuits 33 may include a plurality of memory cells, a plurality of transistors, a plurality of logic circuits or a plurality of active/passive elements. The plurality of internal interconnections 35 may include input/output pads, power/ground pads, internal connection conductive patterns or combinations thereof. The plurality of internal interconnections 35 may be connected to the plurality of integrated circuits 33. Each of the plurality of chip top interconnections 42 may be connected to a corresponding one among the plurality of internal interconnections 35.

A chip top insulating layer 46 may be formed on the interlayer insulating layer 31 and the plurality of chip top interconnections 42. The chip top insulating layer 46 may cover the interlayer insulating layer 31 and the plurality of chip top interconnections 42. The chip top insulating layer 46 may completely cover the top surfaces of the plurality of chip top interconnections 42. The top surface of the chip top insulating layer 46 may be planarized using a planarization process. The planarization process may include a chemical mechanical polishing (CMP) process, an etch-back process or a combination thereof. The thickness of the substrate 21 may be reduced by partially removing the back surface of the substrate 21.

Each of the interlayer insulating layer 31 and the chip top insulating layer 46 may be formed as a single layer or a multi-layer. Each of the interlayer insulating layer 31 and the chip top insulating layer 46 may include silicon oxide, silicon nitride, silicon oxynitride, low-K dielectric, high-K dielectric or a combination thereof. Each of the plurality of internal interconnections 35, the plurality of guard rings 37 and the plurality of chip top interconnections 42 may be formed as a single layer or a multi-layer. Each of the plurality of internal interconnections 35, the plurality of guard rings 37 and the plurality of chip top interconnections 42 may include a conductive material such as metal, metal oxide, metal nitride, metal silicide, polysilicon, conductive carbon or a combination thereof. In an embodiment, each of the plurality of chip top interconnections 42 may include Al, Cu, W, WN, Ti, TIN, Ta, TaN, Co, Ru, Ni, Pt or a combination thereof.

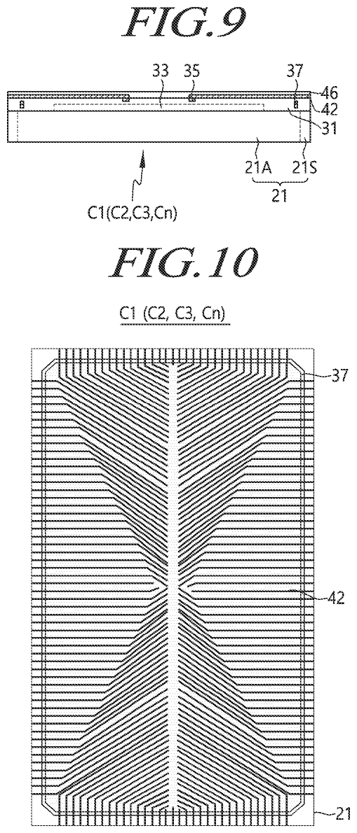

Referring to FIGS. 9 and 10, the plurality of semiconductor chips C1, C2, C3, . . . and Cn may be divided by cutting the outer regions 21S using a dicing process. Each of the plurality of semiconductor chips C1, C2, C3, . . . and Cn may include the substrate 21, the interlayer insulating layer 31, the plurality of integrated circuits 33, the plurality of internal interconnections 35, the guard ring 37, the plurality of chip top interconnections 42, and the chip top insulating layer 46.

The substrate 21 may include the active region 21A and the outer region 21S. The outer region 21S may be a continuous region formed on a side edge of the active region 21A. The plurality of integrated circuits 33, the plurality of internal interconnections 35 and the guard ring 37 may be formed in the interlayer insulating layer 31 over the active region 21A. The guard ring 37 may be formed to surround the integrated circuits 33. The guard ring 37 may be formed adjacent to the outer region 21S.

Each of the plurality of chip top interconnections 42 may cross over the guard ring 37 in the active region 21A and extend to the outer region 21S. The side surfaces of the plurality of chip top interconnections 42 may be exposed. The side surfaces of the outer region 21S, the interlayer insulating layer 31, the plurality of chip top interconnections 42 and the chip top insulating layer 46 may be vertically aligned. The side surfaces of the outer region 21S, the interlayer insulating layer 31, the plurality of chip top interconnections 42 and the chip top insulating layer 46 may be coplanar form the same plane. The chip top insulating layer 46 may have a planarized top surface.

Referring to FIG. 11, an adhesive layer 53 may be formed on a carrier 51. The plurality of semiconductor chips C1, C2, C3, . . . and Cn may be sequentially stacked on the adhesive layer 53. The plurality of semiconductor chips C1, C2, C3, . . . and Cn may include a first semiconductor chip C1, a second semiconductor chip C2, a third semiconductor chip C3 and an nth semiconductor chip Cn. The first semiconductor chip C1, the second semiconductor chip C2, the third semiconductor chip C3 and the nth semiconductor chip Cn may configure a stack structure CST. A plurality of the stack structures CST may be repeatedly formed on the adhesive layer 53 at regular intervals. One another semiconductor chip or a plurality of other semiconductor chips may be additionally stacked between the third semiconductor chip C3 and the nth semiconductor chip Cn, but the description thereof will be omitted for the sake of simplicity in explanation.

In an embodiment, the substrate 21 of the first semiconductor chip C1 may be attached onto the adhesive layer 53. The substrate 21 of the second semiconductor chip C2 may be attached onto the chip top insulating layer 46 of the first semiconductor chip C1. In a manner similar to the second semiconductor chip C2, the third semiconductor chip C3 and the nth semiconductor chip Cn may be sequentially attached onto the second semiconductor chip C2. In an embodiment, other adhesive layers may be additionally formed between the plurality of semiconductor chips C1, C2, C3, . . . and Cn, but the description thereof will be omitted for the sake of simplicity in explanation.

Referring to FIG. 12, the second semiconductor chip C2 may be stacked on the first semiconductor chip C1. The third semiconductor chip C3 may be stacked on the second semiconductor chip C2. The bottom surface of the substrate 21 of the second semiconductor chip C2 may directly contact the top surface of the chip top insulating layer 46 of the first semiconductor chip C1. In a manner similar to the second semiconductor chip C2, the bottom surface of the substrate 21 of the third semiconductor chip C3 may directly contact the top surface of the chip top insulating layer 46 of the second semiconductor chip C2. The side surfaces of the first semiconductor chip C1, the second semiconductor chip C2 and the third semiconductor chip C3 may be vertically aligned. The side surfaces of the outer regions 21S, the interlayer insulating layers 31, the plurality of chip top interconnections 42 and the chip top insulating layers 46 may be exposed.

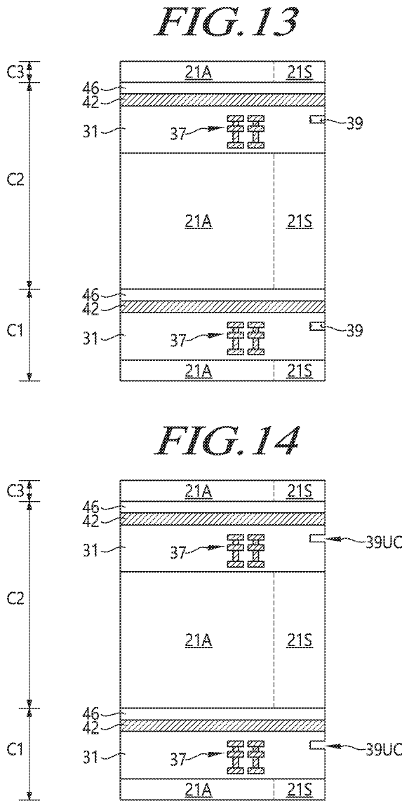

Referring to FIG. 13, a dummy pattern 39 may be formed in the interlayer insulating layer 31 of the second semiconductor chip C2. The dummy pattern 39 may be formed in the interlayer insulating layer 31 over the outer region 21S. The dummy pattern 39 may be formed between the bottom surfaces of the plurality of chip top interconnections 42 and the top surface of the substrate 21. The interlayer insulating layer 31 may be interposed between the dummy pattern 39 and the plurality of chip top interconnections 42. Likewise, the interlayer insulating layer 31 may be interposed between the dummy pattern 39 and the outer regions 21S of the substrates 21. One of the side surfaces of the dummy pattern 39 that is opposite to the side surface that is closer to the guard ring 37 may be exposed. Each of the first semiconductor chip C1, the third semiconductor chip C3 and the nth semiconductor chip Cn may include a dummy pattern 39 similar to the dummy pattern 39 of the second semiconductor chip C2. The dummy pattern 39 may include a test pattern, an align key or a part of a combination thereof. The dummy pattern 39 may include a conductive material.

Referring to FIG. 14, by removing the dummy pattern 39, a first undercut region 39UC may be formed.

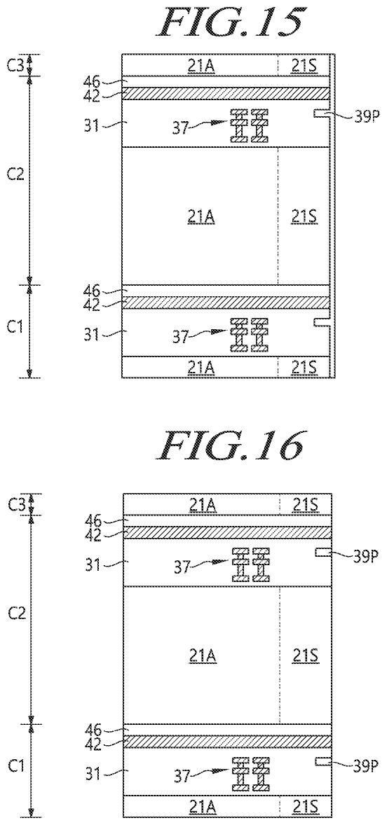

Referring to FIG. 15, a capping layer 39P which fills the first undercut region 39UC may be formed on the side surface of the stack structure CST.

Referring to FIG. 16, the capping layer 39P may be preserved only in the first undercut region 39UC using an etch-back process.

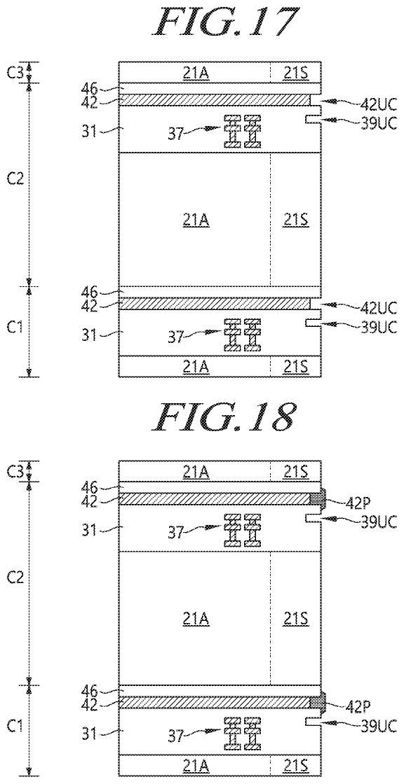

Referring to FIG. 17, a plurality of second undercut regions 42UC may be formed by partially removing an edge portion from each of the plurality of chip top interconnections 42.

Referring to FIG. 18, a plurality of conductive plugs 42P may be formed in the plurality of second undercut regions 42UC.

In an embodiment, a selective metal deposition process may be used to form the plurality of conductive plugs 42P. The plurality of chip top interconnections 42 may include Cu or Al, and the plurality of conductive plugs 42P may include Co.

In an embodiment, a thin film forming process and an etch-back process may be used to form the plurality of conductive plugs 42P.

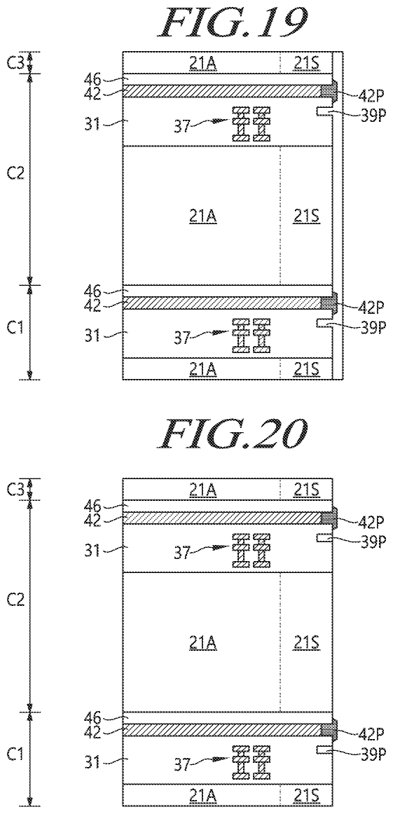

Referring to FIG. 19, a capping layer 39P which fills the first undercut region 39UC may be formed on the side surface of the stack structure CST. The capping layer 39P may include silicon oxide, silicon nitride, silicon oxynitride or a combination thereof.

Referring to FIG. 20, the capping layer 39P may be preserved in the first undercut region 39UC using an etch-back process.

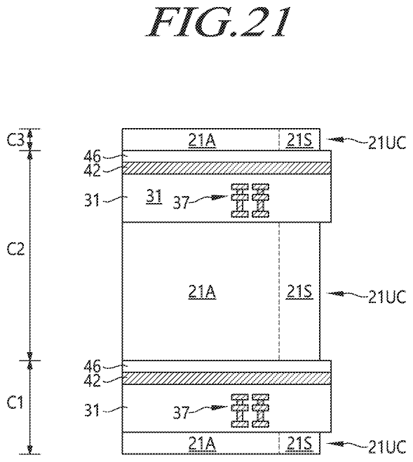

Referring to FIG. 21, a plurality of third undercut regions 21UC may be formed by etching back the side surfaces of the substrates 21. The top surface of the chip top insulating layer 46 of the second semiconductor chip C2 may be exposed. The bottom surface of the interlayer insulating layer 31 of the second semiconductor chip C2 may be exposed. Similar to the second semiconductor chip C2, the bottom surfaces of the interlayer insulating layers 31 of the first semiconductor chip C1, the third semiconductor chip C3 and the nth semiconductor chip Cn may be exposed. The top surfaces of the chip top insulating layers 46 of the first semiconductor chip C1 and the third semiconductor chip C3 may be exposed.

Referring to FIG. 22, a plurality of the insulating patterns 61 may be formed on the side surface of the stack structure CST in the third undercut regions 21UC. The plurality of the insulating patterns 61 may cover the side surfaces of the substrates 21. The plurality of the insulating patterns 61 may include oxide, nitride or a combination thereof. In an embodiment, the plurality of the insulating patterns 61 may include silicon oxide, silicon nitride, silicon oxynitride or a combination thereof.

Referring to FIG. 23, in an embodiment, a selective oxidation process may be used to form the plurality of the insulating patterns 61. A low-temperature oxidation process may be used to form the plurality of the insulating patterns 61. For example, in order to form the plurality of the insulating patterns 61, a selective oxidation process performed at a temperature range of from about 80° C. to about 350° C. using an atomic layer deposition (ALD) device, a plasma-enhanced ALD (PEALD) device or a cyclic deposition device may be used. In an embodiment, the plurality of the insulating patterns 61 may include silicon oxide, silicon oxynitride or a combination thereof.

Each of the plurality of the insulating patterns 61 may be aligned on the side surface of the substrate 21. The plurality of the insulating patterns 61 may be formed in the plurality of third undercut regions 21UC, respectively. Each of the plurality of the insulating patterns 61 may be formed to be delimited between the side surface of the substrate 21, the bottom surface of the interlayer insulating layer 31 and the top surface of the chip top insulating layer 46. For example, one of the plurality of the insulating patterns 61 may be formed to be delimited between the side surface of the substrate 21 of the second semiconductor chip C2, the bottom surface of the interlayer insulating layer 31 of the second semiconductor chip C2 and the top surface of the chip top insulating layer 46 of the first semiconductor chip C1. The one of the plurality of the insulating patterns 61 may directly contact the side surface of the substrate 21 of the second semiconductor chip C2, the bottom surface of the interlayer insulating layer 31 of the second semiconductor chip C2 and the top surface of the chip top insulating layer 46 of the first semiconductor chip C1.

While the insulating pattern 61 is formed, as the side surfaces of the plurality of chip top interconnections 42 are oxidated, first metal oxide regions 420 may be formed.

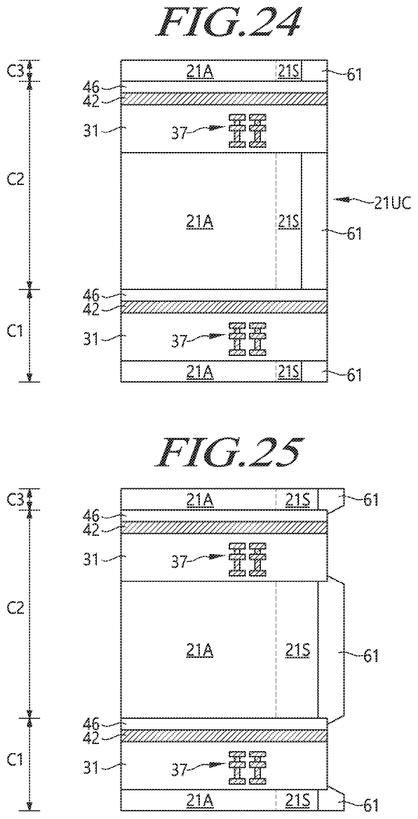

Referring to FIG. 24, by removing the first metal oxide regions 420 using a cleaning process, the side surfaces of the plurality of chip top interconnections 42 may be exposed.

Referring to FIG. 25, each of the plurality of the insulating patterns 61 may protrude outward beyond the side surface of the interlayer insulating layer 31. Each of the plurality of the insulating patterns 61 may partially extend outward till the side surface of an adjacent interlayer insulating layer 31, and may partially extend onto the side surface of an adjacent chip top insulating layer 46.

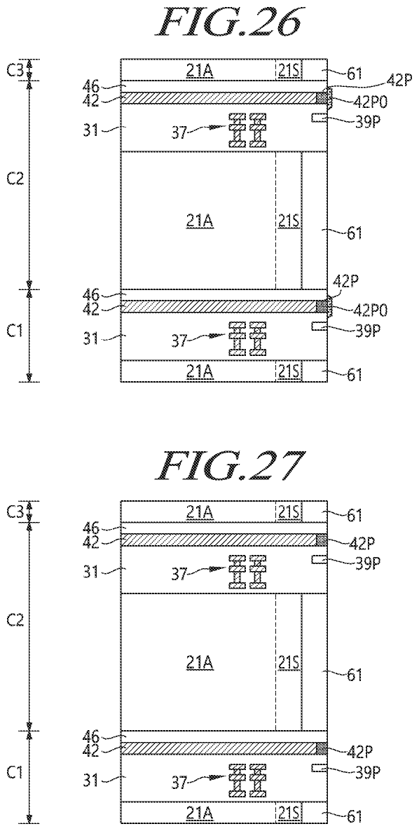

Referring to FIG. 26, second metal oxide 42P0 may be formed on the side surfaces of the plurality of conductive plugs 42P. In an embodiment, the second metal oxide 42P0 may be formed by surface oxidation of the plurality of conductive plugs 42P.

Referring to FIG. 27, by removing the second metal oxide 42P0 using a cleaning process, the side surfaces of the plurality of conductive plugs 42P may be exposed.

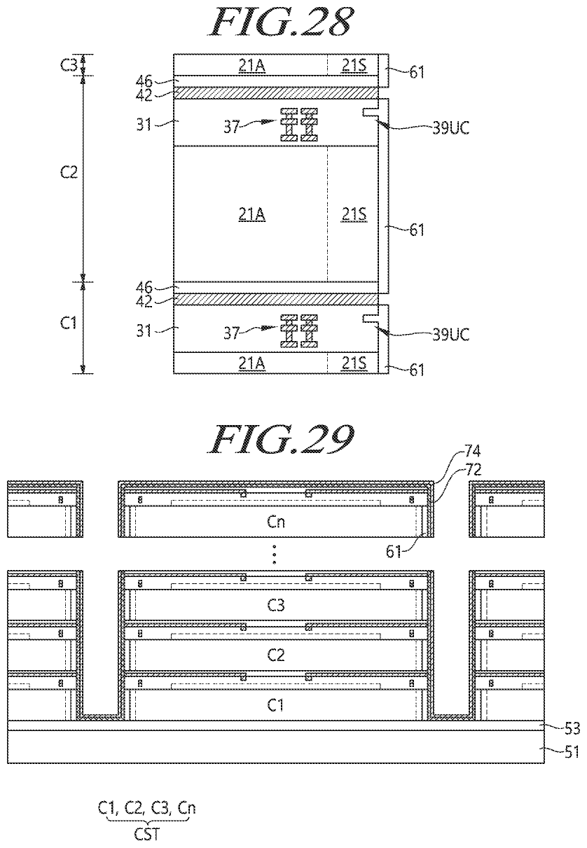

Referring to FIG. 28, a selective deposition process may be used to form an insulating pattern 61. The insulating pattern 61 may be of an integral type meaning that the insulating pattern 61 may fill the first undercut regions 39UC and cover the side surfaces of the substrates 21, the interlayer insulating layers 31 and the chip top insulating layers 46. The insulating pattern 61 may include silicon oxide, silicon nitride, silicon oxynitride or a combination thereof. The side surfaces of the plurality of the chip top interconnections 42 may be exposed.

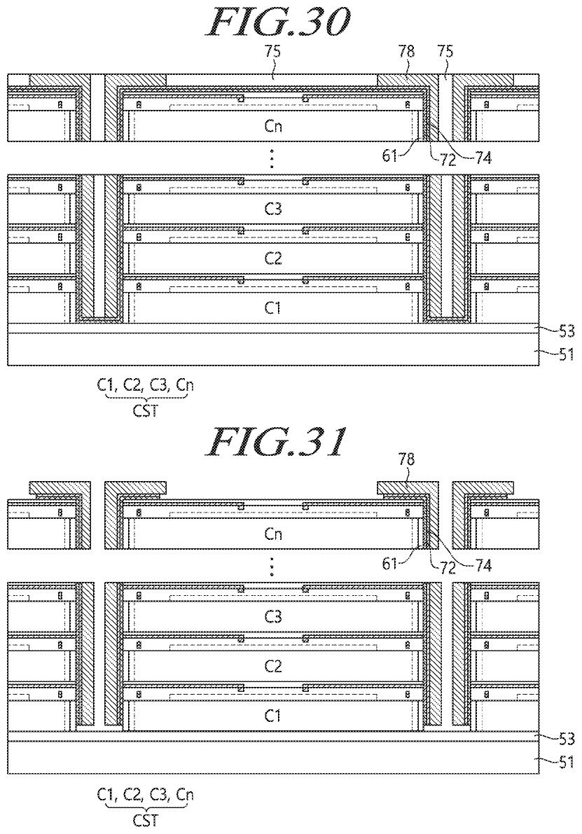

Referring to FIG. 29, a barrier layer 72 and a seed layer 74 may be sequentially formed on the side surfaces and the top surface of the stack structure CST, and on the side surfaces of the plurality of the insulating patterns 61. The plurality of the insulating patterns 61 may be interposed between the barrier layer 72 and the substrates 21. The barrier layer 72 may be connected to the plurality of chip top interconnections 42. The barrier layer 72 may include Ti, TIN, Ta, TaN or a combination thereof. The seed layer 74 may include Cu.

Referring to FIG. 30, a mask pattern 75 partially covering the seed layer 74 may be formed. A plurality of conductive lines 78 may be formed on the seed layer 74 using an electroplating method. The plurality of conductive lines 78 may, for example, include copper (Cu).

Referring to FIG. 31, the mask pattern 75 may be removed, and the seed layer 74 and the barrier layer 72 may be partially removed. The seed layer 74 and the barrier layer 72 may be preserved between the plurality of conductive lines 78 and the plurality of the insulating patterns 61, between the plurality of conductive lines 78 and the interlayer insulating layers 31, between the plurality of conductive lines 78 and the plurality of chip top interconnections 42 and between the plurality of conductive lines 78 and the chip top insulating layer 46. Removing the barrier layer 72 may include an over-etch process. Undercut regions may be formed under the plurality of conductive lines 78.

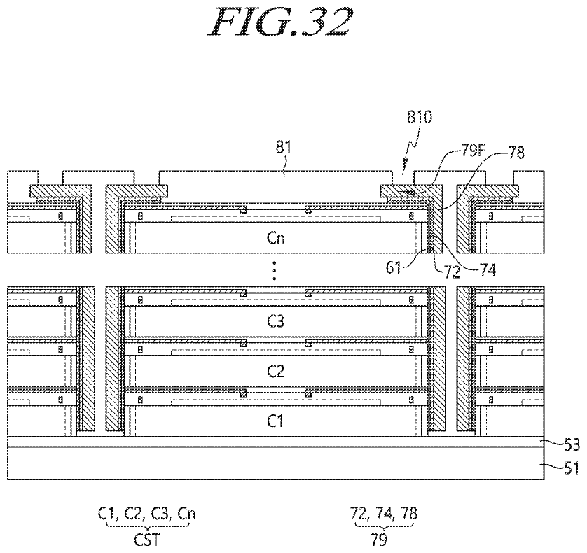

Referring to FIG. 32, the barrier layer 72, the seed layer 74 and the plurality of conductive lines 78 may configure a plurality of side interconnections 79. A protective insulating layer 81 which covers the plurality of the stack structures CST, the plurality of the insulating patterns 61 and the plurality of the side interconnections 79 may be formed on the carrier 51. The protective insulating layer 81 may include polyimide isoindro quindzoline (PIQ).

Each of the plurality of the side interconnections 79 may include an external connection terminal 79F. Openings 810 exposing the external connection terminals 79F may be formed through the protective insulating layer 81. In an embodiment, the external connection terminals 79F may be formed on the top surfaces of the plurality of the stack structures CST.

Referring to FIG. 1 again, the plurality of the stack structures CST may be respectively divided using a singulation process. The carrier 51 and the adhesive layer 53 may be removed.

Although exemplary embodiments of the disclosure have been described for illustrative purposes, those skilled in the art will appreciate that various modifications, additions and substitutions are possible, without departing from the scope of the disclosure. Therefore, the embodiments disclosed above and in the accompanying drawings should be considered in a descriptive sense only and not for limiting the technological scope. The technological scope of the disclosure is not limited by the embodiments and the accompanying drawings.

What is claimed is:

1. A semiconductor device comprising:
a stack structure having a plurality of semiconductor chips, each of the plurality of semiconductor chips having an interlayer insulating layer disposed over or on a substrate, a chip top interconnection over or on the interlayer insulating layer and a chip top insulating layer over or on the chip top interconnection;
a side interconnection disposed over or on a side surface of the stack structure, the side interconnection being connected to the chip top interconnection; and
a plurality of insulating patterns disposed between the stack structure and the side interconnection,
wherein each of the plurality of insulating patterns directly contacts a side surface of the substrate and the interlayer insulating layer of an adjacent one among the plurality of the semiconductor chips.

2. The semiconductor device according to claim 1, wherein the side interconnection directly contacts the plurality of insulating patterns, the interlayer insulating layer and the chip top insulating layer.

3. The semiconductor device according to claim 1, wherein
the plurality of semiconductor chips comprise first to third semiconductor chips which are sequentially stacked, and
one of the plurality of insulating patterns of the second semiconductor chip is aligned with a side surface of the substrate of the second semiconductor chip.

4. The semiconductor device according to claim 3, wherein one of the plurality of insulating patterns of the second semiconductor chip directly contacts a side surface of the substrate of the second semiconductor chip, a bottom surface of the interlayer insulating layer of the second semiconductor chip and a top surface of the chip top insulating layer of the first semiconductor chip.

5. The semiconductor device according to claim 3, wherein
a lowermost end of one of the plurality of insulating patterns is limited to a level higher than an uppermost end of the chip top interconnection of the first semiconductor chip, and
an uppermost end of one of the plurality of insulating patterns is limited to a level lower than a lowermost end of the chip top interconnection of the second semiconductor chip.

6. The semiconductor device according to claim 3, wherein
the substrate of the second semiconductor chip directly contacts the chip top insulating layer of the first semiconductor chip, and
the substrate of the third semiconductor chip directly contacts the chip top insulating layer of the second semiconductor chip.

7. The semiconductor device according to claim 3, wherein one of the plurality of insulating patterns protrudes out of the interlayer insulating layer adjacent thereto.

8. The semiconductor device according to claim 1, wherein
the substrate comprises an active region and an outer region which is continuous and covers a side edge of the active region, and
the chip top interconnection extends from the active region onto the outer region.

9. The semiconductor device according to claim 8, further comprising:
a guard ring disposed in the interlayer insulating layer over the active region adjacent to the outer region,
wherein the chip top interconnection crosses the guard ring.

10. The semiconductor device according to claim 8, further comprising:
a conductive plug disposed between the chip top interconnection and the side interconnection, and having substantially the same thickness as the chip top interconnection.

11. The semiconductor device according to claim 10, wherein the conductive plug is disposed between the interlayer insulating layer and the chip top insulating layer over the outer region.

12. The semiconductor device according to claim 8, further comprising:
a capping layer disposed in the interlayer insulating layer over the outer region, and directly contacting the side interconnection.

13. The semiconductor device according to claim 1, wherein
the chip top insulating layer completely covers a top surface of the chip top interconnection, and
the chip top insulating layer includes a planarized top surface.

14. The semiconductor device according to claim 1, further comprising:
a protective insulating layer disposed over or on the stack structure, the plurality of insulating patterns and the side interconnection.

15. The semiconductor device according to claim 14, wherein
the side interconnection comprises an external connection terminal which extends over or on the stack structure, and
the external connection terminal is exposed through an opening which passes through the protective insulating layer.

16. The semiconductor device according to claim 14, wherein the protective insulating layer covers a lowermost end of the side interconnection.

17. A semiconductor device comprising:
a stack structure having a plurality of semiconductor chips, each of the plurality of semiconductor chips having an interlayer insulating layer disposed over or on a substrate, a chip top interconnection disposed over or on the interlayer insulating layer and a chip top insulating layer disposed over or on the chip top interconnection;
a side interconnection disposed over or on a side surface of the stack structure, and connected to the chip top interconnection; and
a plurality of insulating patterns disposed between the stack structure and the side interconnection, each of the plurality of insulating patterns being aligned with a side surface of the substrate.

18. The semiconductor device according to claim 17, wherein the side interconnection directly contacts the plurality of insulating patterns, the interlayer insulating layer and the chip top insulating layer.

19. A semiconductor device comprising:
a stack structure having a plurality of semiconductor chips, each of the plurality of semiconductor chips having an interlayer insulating disposed over or on a substrate, a chip top interconnection disposed over or on the interlayer insulating layer and a chip top insulating layer disposed over or on the chip top interconnection;
a side interconnection disposed over or on a side surface of the stack structure, and connected to the chip top interconnection; and
an insulating pattern between the stack structure and the side interconnection,
wherein the insulating pattern directly contacts side surfaces of the substrate, the interlayer insulating layer and the chip top insulating layer.

20. The semiconductor device according to claim 19, wherein the side interconnection is connected to the chip top interconnection through the insulating pattern.
